(19) United States
(12) Patent Application Publication
(10) Pub. No.: US 2012/0007097 A1
(43) Pub. Date: Jan. 12, 2012

(54) SCHOTTKY DIODE WITH COMBINED FIELD PLATE AND GUARD RING

(75) Inventor: Francois Hebert, San Mateo, CA (US)

(73) Assignee: INTERSIL AMERICAS INC., Milpitas, CA (US)

(21) Appl. No.: 12/944,163

(22) Filed: Nov. 11, 2010

Related U.S. Application Data
(60) Provisional application No. 61/362,499, filed on Jul. 8, 2010.

(51) Int. Cl. H01L 29/20; H01L 29/872; H01L 21/329

(52) U.S. Cl. 257/76; 438/570; 257/484; 257/E29.089; 257/E21.359; 257/E29.338

(57) ABSTRACT

A Schottky diode comprising a merged guard ring and field plate defining a Schottky contact region is provided. A Schottky metal is formed over at least partially over the Schottky contact region and at least partially over the merged guard ring and field plate.

### CROSS-REFERENCE TO RELATED APPLICATIONS

This application is related to U.S. provisional patent application Ser. No. 61/362,499 (attorney docket number SE-2808) entitled “SCHOTTKY DIODE WITH COMBINED FIELD PLATE AND GUARD RING,” filed on Jul. 8, 2010 and referred to herein as the '499 application. The present application hereby claims the benefit of U.S. Provisional Patent Application No. 61/362,499. The '499 application is hereby incorporated herein by reference.

### DRAWINGS

FIG. 1A is a cross sectional view of one embodiment of a vertical Schottky diode with a positively doped Gallium Nitrate (P-GaN) merged guard ring and field plate.

FIG. 1B is a cross sectional view of one embodiment of a vertical Schottky diode with a double merged guard ring and field plate.

FIG. 2A is a cross sectional view of one embodiment of a vertical Schottky diode having a single level self-aligned field plate.

FIG. 2B is a cross sectional view of one embodiment of a vertical Schottky diode having a double field plate.

FIGS. 3A and 3B are cross sectional views of embodiments of a vertical Schottky diode having a double merged guard ring and field plate.

FIGS. 4A and 4B are cross sectional views of embodiments of a vertical Schottky diode having a P-epi ring.

FIGS. 5A through 5K are cross sectional views of one embodiment of a vertical Schottky diode corresponding to one embodiment of a method of fabricating the vertical Schottky diode.

FIGS. 6A through 6I are cross sectional views of an alternative embodiment of a vertical Schottky diode corresponding to one embodiment of a method of fabricating the vertical Schottky diode.

FIG. 7 is a cross sectional view of one embodiment of a lateral PN junction diode with a double field plate.

FIGS. 8A and 8B are cross sectional views of embodiments of a lateral Schottky diode having P-GaN overlap.

FIGS. 9A through 9F are cross sectional views of one embodiment of a lateral diode corresponding to one embodiment a method of fabricating the lateral diode.

FIG. 10 is a block diagram of a device comprising at least one diode with a field plated guard ring.

Like reference numbers and designations in the various drawings indicate like elements.

### DETAILED DESCRIPTION

Some embodiments described herein provide diodes that combine a guard ring with a self-aligned field plate structure. Embodiments of the diodes include vertical Schottky diodes, lateral Schottky diodes, and lateral P-N junction diodes. In some embodiments, the guard ring and field plate are formed at the same time. Other embodiments described herein comprise double or triple field plates.

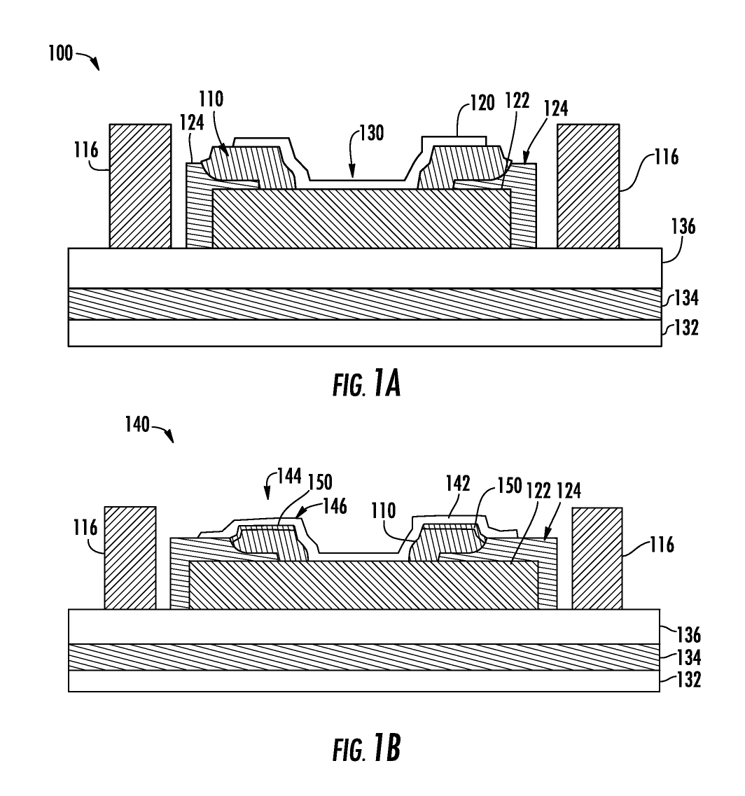

FIG. 1A is a cross sectional view of one embodiment of a vertical Schottky diode 100 with a merged guard ring and field plate 110. The merged guard ring and field plate 110 is a breakdown voltage enhancing structure that provides the functionality of both a field plate and a guard ring. As shown in FIG. 1A, the merged guard ring and field plate 110 comprises positively doped (p-type) gallium nitride (P-GaN). In other embodiments, the merged guard ring and field plate 110 comprises positively doped aluminium gallium nitride (P-AlGaN), positively doped indium aluminum nitride (P-InAlN), or positively doped indium gallium nitride (InGaN). One embodiments of the P-type dopant for the GaN, AlGaN, InAlN, and InGaN embodiments is magnesium (Mg).

The Schottky diode 100 comprises a substrate 132, over which a buffer layer 134 is formed. A cathode layer 136 is formed from over the buffer layer 134 and comprises GaN N+. An annular shaped cathode 116 is formed over a portion of the GaN N+ cathode layer 136. A voltage sustaining layer 122 is also formed over a portion of the GaN N+ cathode layer 136. In the embodiment of FIG. 1A, the voltage sustaining layer 122 comprises an N-epitaxial layer formed of GaN. The voltage sustaining layer 122 defines a vertical breakdown voltage for the vertical Schottky diode 100 as a function of the doping concentration and thickness of the GaN N+ cathode layer 136. For example, a voltage sustaining layer 122 having a vertical thickness of approximately 6 to 9 microns (μm) and doping concentrations of approximately 1E15 to 1E17 (atoms per cm³) yields a breakdown voltage of approximately 500 to 800 volts (V).

The Schottky diode 100 uses a metal-semiconductor junction as a Schottky contact region 130 (also referred to as a barrier region or a Schottky contact opening). The Schottky contact region 130 is an area above the voltage sustaining layer 122 that is bounded by the merged guard ring and field plate 110. The field plate portion of the merged guard ring and field plate 110 is a gate that couples to the voltage sustaining layer 122 with a voltage between the voltage sustaining layer 122 and a Schottky metal 120.

The Schottky metal 120 functions as an anode. In the embodiment shown in FIG. 1A, Schottky metal 120 is formed over at least part of the voltage sustaining layer 122. Current flows from the Schottky metal 120 through the voltage sustaining layer 122, through the GaN N+ cathode layer 136 to the cathode 116. Embodiments implementing lower voltage levels can have a thinner voltage sustaining layer 122 or have a higher doping concentration than embodiments implementing higher voltage levels. Similarly, for embodiments having higher voltage levels will have thicker voltage sustaining layer 122 or have a lower doping concentration.

The merged guard ring and field plate 110 is self-aligned and is partly formed over a dielectric 124. Self-alignment indicates that the field plate and guard ring are formed at the same time with a single mask to create the merged guard ring and field plate 110 with the same structure and shape. This eliminates the need for an additional mask which would need alignment. In one embodiment, the merged guard ring and field plate 110 comprises an approximately ring shaped layer formed along the edge of the dielectric 124 that defines Schottky contact region 130 in the region within and underneath the ring of the merged guard ring and field plate 110. In one embodiment, the Schottky metal 120 is formed over at least part of the Schottky contact region 130 and at least part of the merged guard ring and field plate 110.

Typical Schottky diodes have significant leakage current at high voltage because of low barrier height or non-ideal termination at the periphery of the Schottky contact region 130. This leakage is generally a function of the reverse applied voltage because of the high and concentrated electric field at the periphery of the Schottky contact region 130. In FIG. 1A, the merged guard ring and field plate 110 provides field plating to reduce the peak electric field at the Schottky contact region 130. The merged guard ring and field plate 110 is formed as a conductive field plate which also acts as a p-type guard ring within the n-type voltage sustaining layer 122. The merged guard ring and field plate 110 also provides shielding of the periphery of the Schottky contact region 130 as well as the exposed Schottky metal 120, especially at high voltages. In the vertical Schottky diode 100, current flows in the central region of the voltage sustaining layer 122 located under the central region defined or encircled within the merged guard ring and field plate 110 (that is, the Schottky contact region 130), which controls the electric field, and passes through the anode Schottky metal 120.

Embodiments of the Schottky metal 120 comprise NiAu or any other suitable material for the particular semiconductor and application, including but not limited to, nickel (Ni), titanium (Ti), cobalt (Co), aluminum (Al), platinum (Pt), tantalum (Ta), and the like. Some embodiments of a vertical diode comprise an ohmic contact to the metallization layer (for example, the Schottky metal 120) rather than the Schottky-like contact to the metallization layers. In such an embodiment, Ti/Al/Au, Ti/Al/Ni/Au, or another combination of layers, are annealed at approximately 800° C. or higher to form ohmic (that is, non rectifying) contacts to the p-type merged guard ring and field plate 110.

The voltage sustaining layer 122 is a gallium nitride (GaN) N-epitaxial layer. In other embodiments, the voltage sustaining layer 122 comprises other materials including, but not limited to, silicon (Si), germanium (Ge), SiGe, aluminum gallium nitride (AlGaN), indium gallium nitride (InGaN), indium phosphide (InP), gallium arsenide (GaAs), and the like. Embodiments of the voltage sustaining layer 122 comprise doped or undoped materials. The substrate 132 can comprise any suitable substrate material, including but not limited to, Si, sapphire, diamond, silicon carbide, GaN, InP, and the like. Some embodiments of the dielectric layer 124 comprise a silicon nitride, a silicon oxynitride, oxide, aluminum nitride, aluminum oxide (Al₂O₃), or combinations thereof, including embodiments having multiple layers. Another embodiment of the dielectric layer 124 is a passivation film, such as polyimide with a thickness in the range of approximately 1 to 20 μm, benzo cyclo butane (BCB), or SU-8 photo resist with a thickness in the range of approximately 1 to 15 μm.

In the embodiment shown in FIG. 1A, the merged guard ring and field plate 110 comprises p-GaN formed using selective epitaxial growth (SEG) or epitaxial lateral overgrowth (ELO). SEG is a technique for epitaxially growing a semiconductor material on a semiconductor substrate. In FIG. 1A, the merged guard ring and field plate 110 is grown using SEG on the voltage sustaining layer 122. A p-n junction is formed between the p-type GaN field plate 110 and the n-type voltage sustaining layer 122. Implantation is not needed when SEG is used. The growth of an epitaxial layer is performed at a lower temperature than typical temperatures used for annealing. For example, some implementations of epitaxial growth are in the 950-1100° C. range, while some implementations of implant annealing are around approximately 1200° C. Because the Schottky diode 100 is not exposed to the high temperature during an annealing step, SEG is more compatible with different layer structures. For example, SEG is compatible with thinner GaN layers because the risk of diffusion from the GaN N+ layer is reduced, as well as the reduction of other stresses. Growing the layer using SEG provides a single step for forming the P-GaN merged guard ring and field plate 110 because it can be grown laterally from the interface of voltage sustaining layer 122 (because of ELO, for example).

The P-GaN merged guard ring and field plate 110 grows over curves in the dielectric 124 when it is exposed to a reactor that grows GaN. The curved shape of the dielectric reduces the peak electric field because of the lack of sharp corners and gradual dielectric thickness change. In embodiments of the Schottky diode 100 where the dielectric layer 124 is, for example, silicon dioxide or another oxygen containing dielectric, nucleation of p-type GaN or AlGaN on regions other than a patterned guard ring opening is reduced when the merged guard ring and field plate 110 is selectively grown.

FIG. 1B is a cross sectional view of one embodiment of a vertical Schottky diode 140 with a merged guard ring and double field plate 144. In this embodiment, Schottky metal 142 overlaps a merged guard ring and field plate 110 to form the merged guard ring and double field plate 144. This overlap of the Schottky metal 142 acts as a second field plate (referred to as double field plate 146), forming the merged guard ring and double field plate 144. The merged guard ring and double field plate 144 couples to the voltage sustaining layer 122. The intensity of this coupling depends on the proximity of the merged guard ring and double field plate 144 and the double field plate 146 to the voltage sustaining layer 122.

The shape of an electric field through the diode 140 is variable based on the shape of the merged guard ring and field plate 110 and the double field plate 146. Some embodiments of the merged guard ring and field plate 110 and the double field plate 146 are designed to protect more at the initial contact of the voltage sustaining layer 122 and spread outward and upward as distance from the voltage sustaining layer 122 increases. In other embodiments, the merged guard ring and field plate 110 and the double field plate 146 have layered structures and curves to reduce sharp edges to improve shielding.

In the embodiment shown in FIG. 1B, a doped layer 150 is grown on top of the merged guard ring and field plate 110. The doped layer 150 is an upper portion of the merged guard ring and field plate 110 that is doped to a higher concentration that the lower portion of the merged guard ring and field plate 110. The doped layer 150 provides a low resistance contact between any anode metal electrode and a doped semiconductor layer. When the merged guard ring and field plate 110 is a P-type, the doped layer 150 is a P+ doped layer. The doped layer 150 comprises GaN or AlGaN, for example. The doped layer 150 is relatively thin in comparison to the merged guard ring and field plate 110. In one embodiment, the doped layer 150 is formed through doping only the upper portion of the merged guard ring and field plate 110.

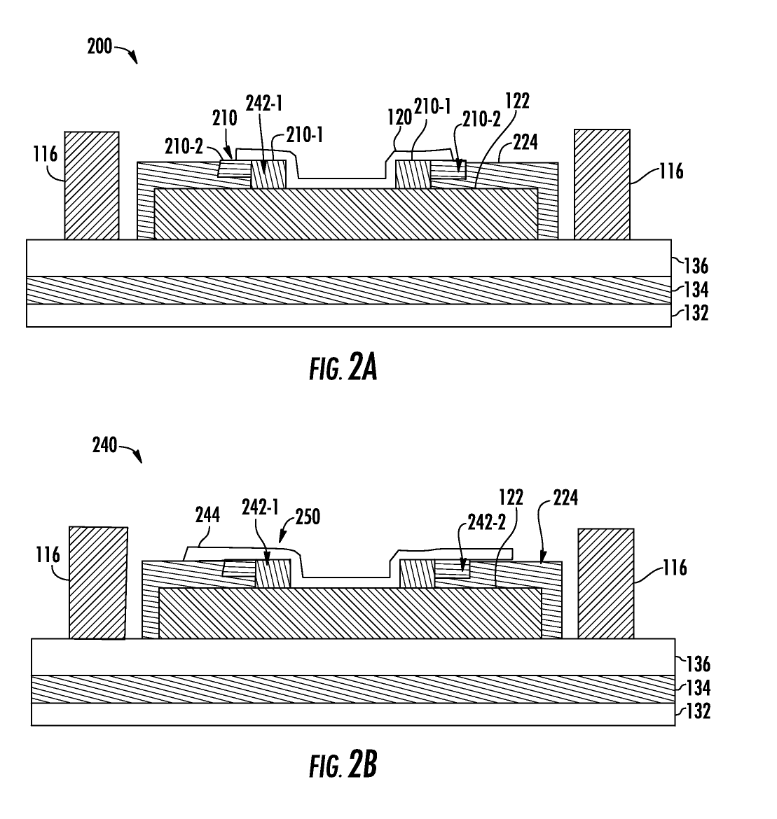

FIG. 2A is a cross sectional view of one embodiment of a vertical Schottky diode 200 having a single level self-aligned merged guard ring and field plate 210. In this embodiment, the merged guard ring and field plate 210 comprises GaN that is not grown selectively. Typically, when semiconductors are grown non-selectively over dielectrics or formed materials, the structure of the resulting semiconductor is amorphous, poly-crystalline, micro-crystalline or nano-crystalline over the non-crystalline semiconductor region, and crystalline material is generally grown over the crystalline semiconductor open window. As shown in FIG. 2A, the merged guard ring and field plate 210 comprises two portions: a guard ring 210-1 and a field plate 210-2. The guard ring 210-1-is mono crystalline, while a field plate 210-2 is of lower quality (that is, has more grain boundaries). This does not cause electrical performance problems since the junction is in the mono-crystalline region of the guard ring 210-1 and current does not flow through the field plate 210-2. In some embodiments, the quality of the field plate 210-2, which is formed over dielectric 224, differs from the quality of the guard ring 210-1 over the voltage sustaining layer 222.

In the embodiment shown in FIG. 2A, the guard ring 210-1 comprises P-GaN grown from a voltage sustaining layer 222 and is of mono-crystalline or higher quality and the field plate 210-2 comprises P-GaN and is poly-, micro-, or nano-crystalline. The GaN is grown non-selectively over the dielectric 224 (comprises, for example, an oxide) and into windows over the voltage sustaining layer 222, resulting in two different types of growth in a single step. Therefore, the merged guard ring and field plate 210 is achieved with a GaN growth process without regard to growth defects of the field plate 210-2, which is a faster and lower temperature process (depending on recipes used in a reactor) than SEG growth. A nitride based dielectric 224 can be used to facilitate the nucleation and growth of the P-type material of the merged guard ring and field plate 210 when, for example, the merged guard ring and field plate 210 is grown using a blanket P-type GaN or AlGaN.

FIG. 2B is a cross sectional view of one embodiment of a vertical Schottky diode 240 having a merged guard ring and double field plate 250. The merged guard ring and double field plate 250 comprises a P-GaN field plate 242-2 which acts as a first field plate and a Schottky metal 244 which acts as a second field plate via overlapping the field plate 242-2 and a guard ring 242-1. The P-GaN guard ring 242-1 and field plate 242-2 are not grown selectively.

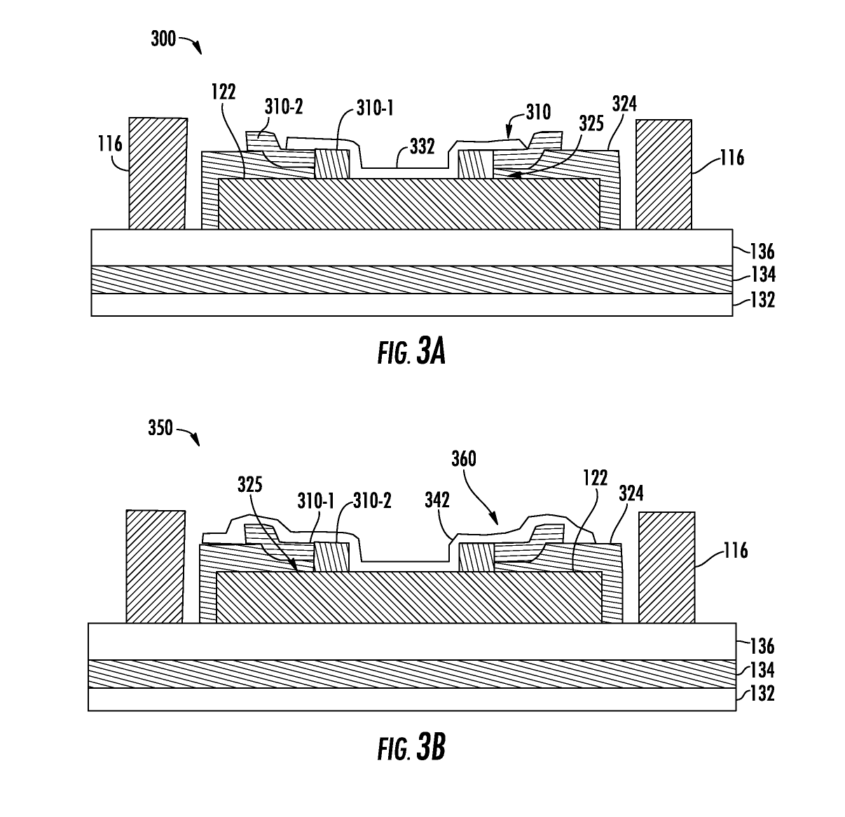

FIGS. 3A and 3B are cross sectional views of embodiments of a vertical Schottky diode having a merged guard ring and double field plate. In FIG. 3A, Schottky diode 300 comprises a merged guard ring and double self-aligned field plate 310 (referred to herein as “double field plate 310”) comprising P-GaN. The double field plate 310 comprises a guard ring 310-1 and a field plate 310-2 formed over a step 325 in dielectric layer 324. In this embodiment, the double field plate 310 comprises P-GaN and is realized using a step 325 in a stepped dielectric 324 and p-guard ring structure. In one embodiment, the P-GaN is formed using epitaxial (“epi”) lateral overgrowth (ELO) techniques. Schottky metal 332 is formed over part of the double field plate 310 and provides double field platting despite not completely covering field plate 310-2.

FIG. 3B shows an alternative Schottky diode 350 to the Schottky diode 300 of FIG. 3A with Schottky metal 342 extending over the double field plate 310. In this embodiment, a double merged guard ring and field plate 360 is realized using Schottky metal 342 and the P-GaN guard ring material.

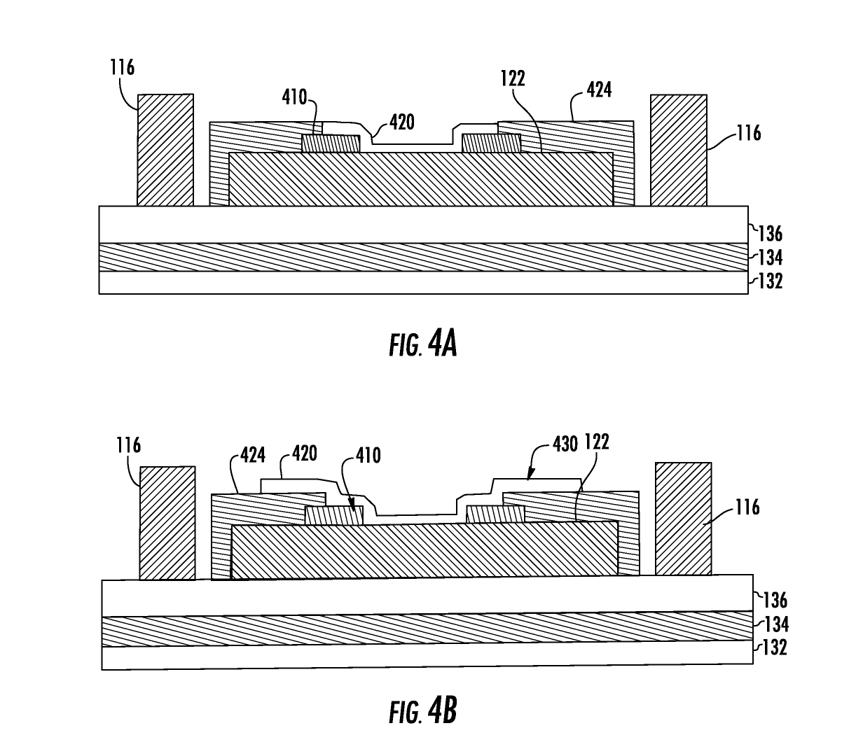

FIGS. 4A and 4B are cross sectional views of embodiments of a vertical Schottky diode having a P-epi guard ring. In FIG. 4A, a P-GaN epi guard ring 410 is formed by growing P-GaN selectively (without ELO), or by growing a blanket p-type epitaxial layer and etching away any portion that is not part of the guard ring 410. Dielectric 424 is formed partially over the P-GaN epi guard ring 410 and contacts Schottky metal 420, wherein the Schottky metal 420 does not overlap the dielectric 424. In FIG. 4B, the Schottky metal 420 extends over the dielectric 424 and forms a field plate 430.

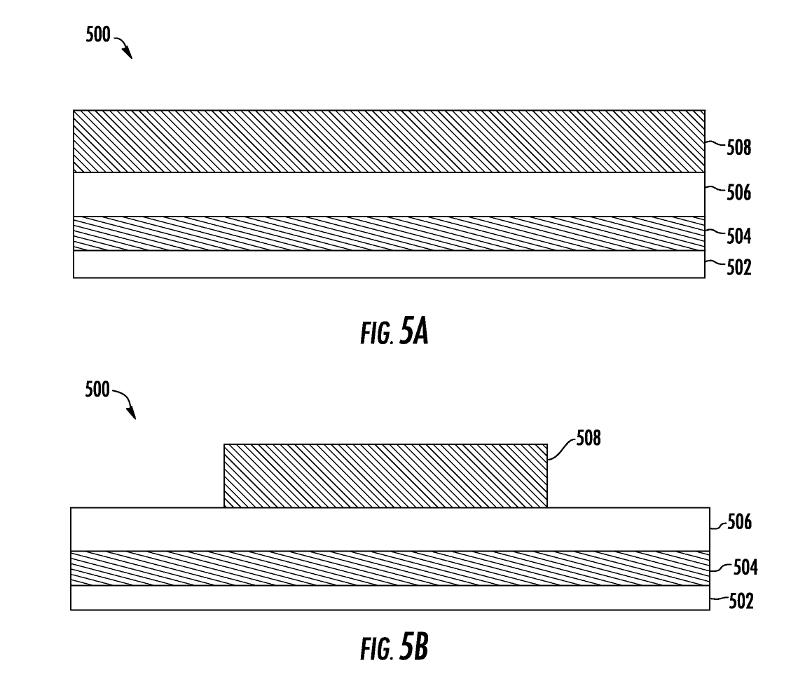

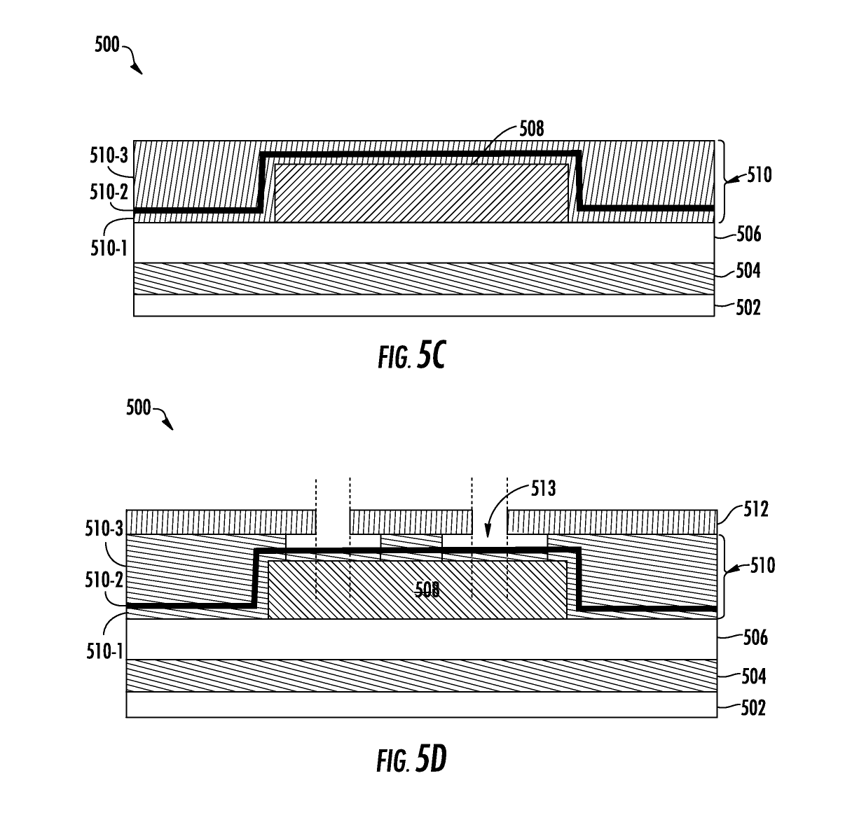

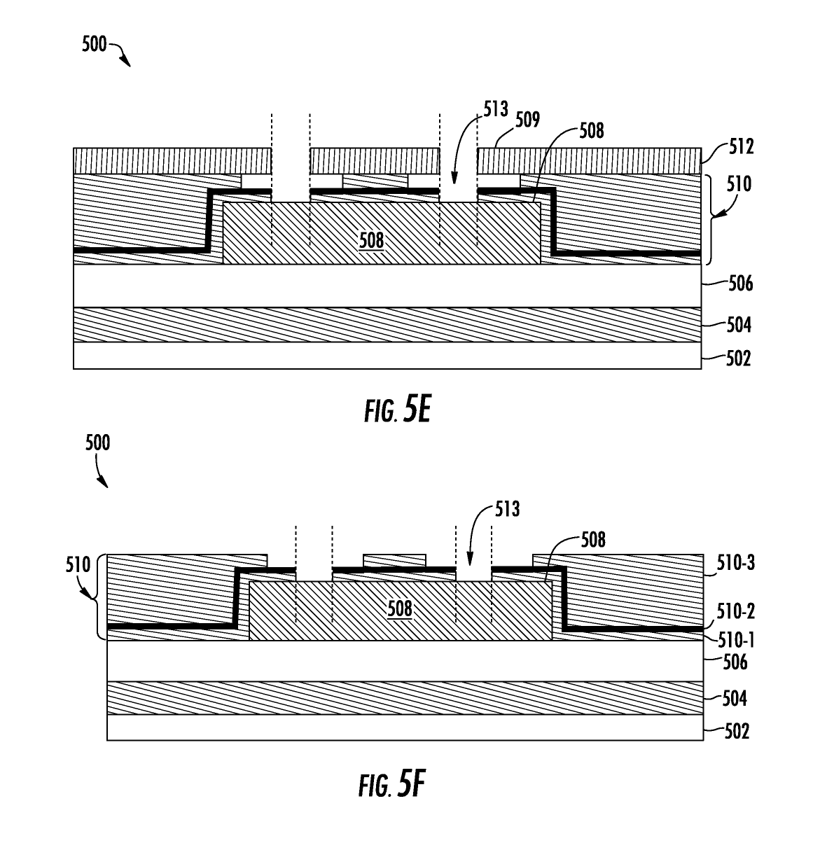

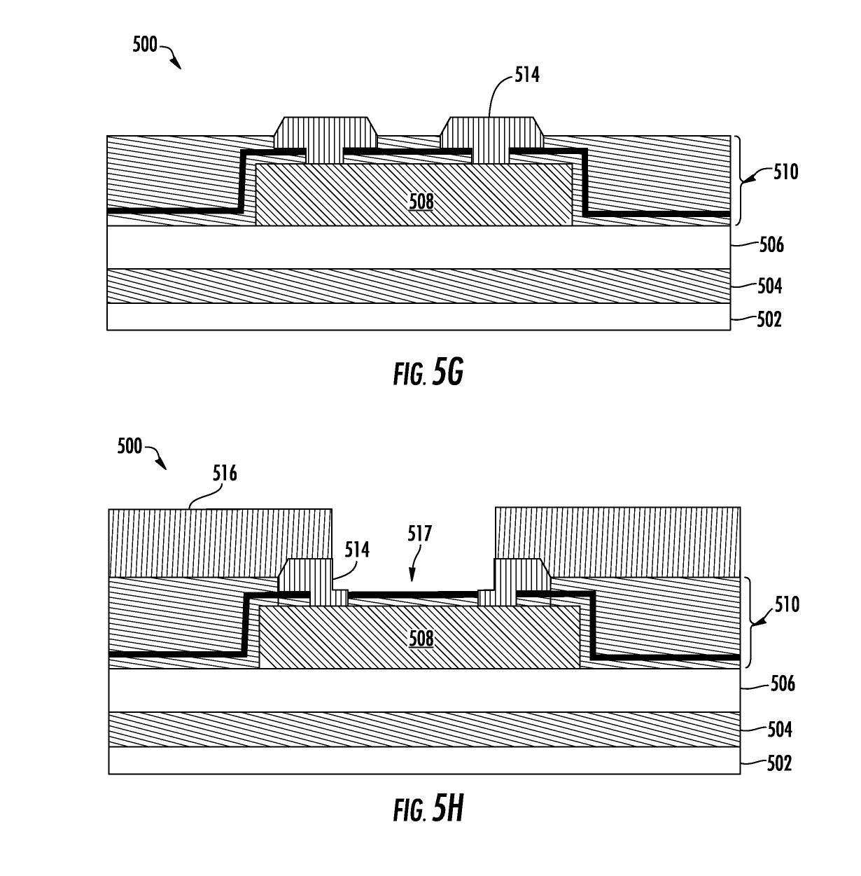

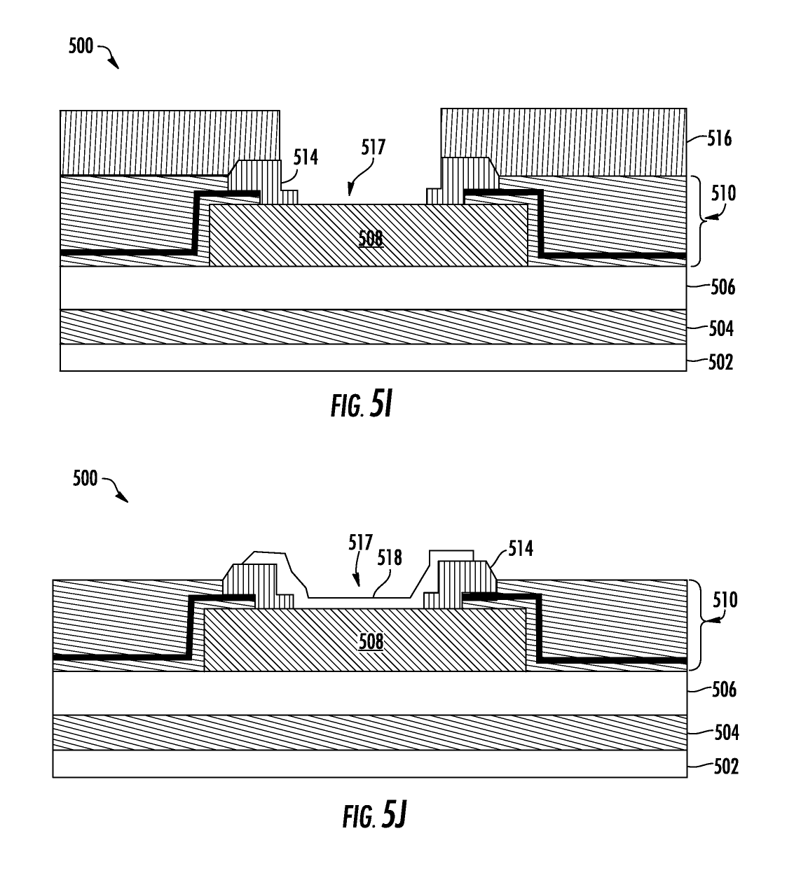

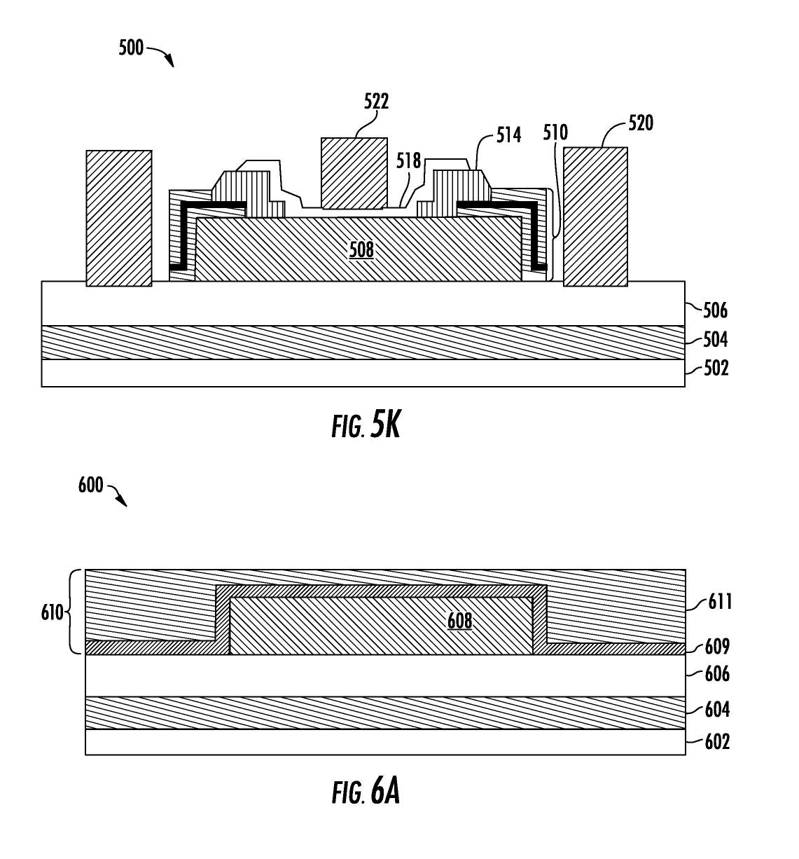

FIGS. 5A through 5L are cross sectional views of one embodiment of a vertical Schottky diode 500 corresponding to one embodiment of a method of fabricating the vertical Schottky diode 500. In one embodiment, the method forms a vertical GaN Schottky diode 500 having a selectively grown P-GaN guard ring 514 which forms a self-aligned field plate 518. FIG. 5A depicts at least one buffer layer 504 formed over a substrate 502. Embodiments of the substrate 502 comprise Si, sapphire, silicon on diamond (SOD), silicon carbide, or the like. An N+ GaN cathode layer 506 (also referred to as a buried layer) is grown over the at least one buffer layer 504. In some embodiments, the buffer layer 504 comprises a plurality of layers. A voltage sustaining layer 508 comprises an N-type drift region grown over the GaN N+ buried layer 506. In one embodiment, the voltage sustaining layer 508 is a GaN N-epi layer. In other embodiments, the doping concentration of the GaN N-epi voltage sustaining layer 508 is approximately 10¹⁵ to 10¹⁷, with thickness in the approximately 1 to 10 micron (μm) range depending on the required breakdown voltage (100 to 1000 V, for example).

Part of the voltage sustaining layer 508 has been etched to expose the cathode layer 506 in FIG. 5B. In one embodiment, mesa etching is performed to expose the cathode layer 506. Etching can be done using dry etching (for example, Inductively Coupled Plasma (ICP)), but other techniques may be used. In FIG. 5C, a dielectric layer 510 is deposited over the exposed cathode layer 508 and remaining voltage sustaining layer 508. The embodiment of the dielectric layer 510 shown in FIG. 5C comprising three layers: a first oxide or oxynitride layer 510-1, a nitride layer 510-2, and a second oxide or oxynitride layer 510-3 (also referred to as a “oxide-nitride-oxide layer”). Other embodiments of the dielectric layer 510 include oxide, oxide-nitride, or any other dielectric material including silicon nitride, AlN, AlSiN, AlSi, N, etc. In FIG. 5D, a photoresist mask 512 is patterned to expose a guard ring pattern 513. The dielectric 510 is etched isotropically to define an extent of a lateral field plate.

FIGS. 5E to 5H illustrate stages in the formation of the guard ring 514. In FIG. 5E, the nitride 510-2 and lower oxide layer 510-1 of the dielectric 510 is dry etched using the original photoresist mask 512 in place to expose a ring of voltage sustaining layer 508. A resist strip has been performed in FIG. 5F. In FIG. 5G, a P-GaN or AlGaN guard ring 514 is grown in the window 513 over the exposed voltage sustaining layer 508. Embodiments of the P-GaN or AlGaN guard ring 514 are grown using SEG or ELO. In one embodiment, any exposed nitride 510-2 is removed selectively if an oxide surface is preferred for SEG/ELO P-GaN or AlGaN growth. One embodiment includes a P+ GaN or AlGaN cap layer grown on top of the P layer to reduce contact resistance to the P layer.

FIG. 5H depicts a Schottky opening 517 that results from the patterning of a Schottky opening mask 516 and an etching of the exposed GaN guard ring 514. In one embodiment, the mask 516 is a simple mask due to the tolerance from the right to left to etch and expose the dielectric 510. In one embodiment, an over-etch is performed to the exposed dielectric 510. The edges of the Schottky opening 517 are within the P-GaN guard ring 514, where it is in contact with the voltage sustaining layer 508. In FIG. 5I, the exposed portion of the nitride 510-2 and oxide layers 510-1 of the dielectric 510 are etched to expose the voltage sustaining layer 508.

In FIG. 5J, a strip resist and clean have been performed. In one embodiment, a Schottky metal 518 is deposited and etched. In another embodiment, a photoresist is deposited, then the Schottky metal 518 is deposited and a lift off of the photoresist is performed. Embodiments of Schottky metals include Ni, NiAu, Pt, Ti, Co, Ta, Ag, Cu, Al as well as others and combinations thereof. A Schottky diode 500 without a Schottky metal field plate is shown in FIG. 5J (similar to the embodiment of FIG. 1A). In another embodiment, the Schottky metal 518 extends past the P-GaN guard ring 514 to provide additional field plating (similar to the embodiment of FIG. 1B). FIG. 5K shows the results of exposing the cathode region, forming the cathode electrodes 520, passivating the device, and performing an interconnect metal 518 patterning and forming an anode electrode 522. Embodiments of the interconnect metal 518 include TiW/Au, Ti/Au, Ti/Al/Au, Ti/TiN/Al, Ti/TiN/AlCu, Ti/Al/Ni/Au, and others as well as combinations thereof. Interconnect metal 518 can act as a field plate by extending outside the lower field plates. In some embodiments of the above described method, the guard ring 514 and internal region of the device are patterned in less steps than typical methods.

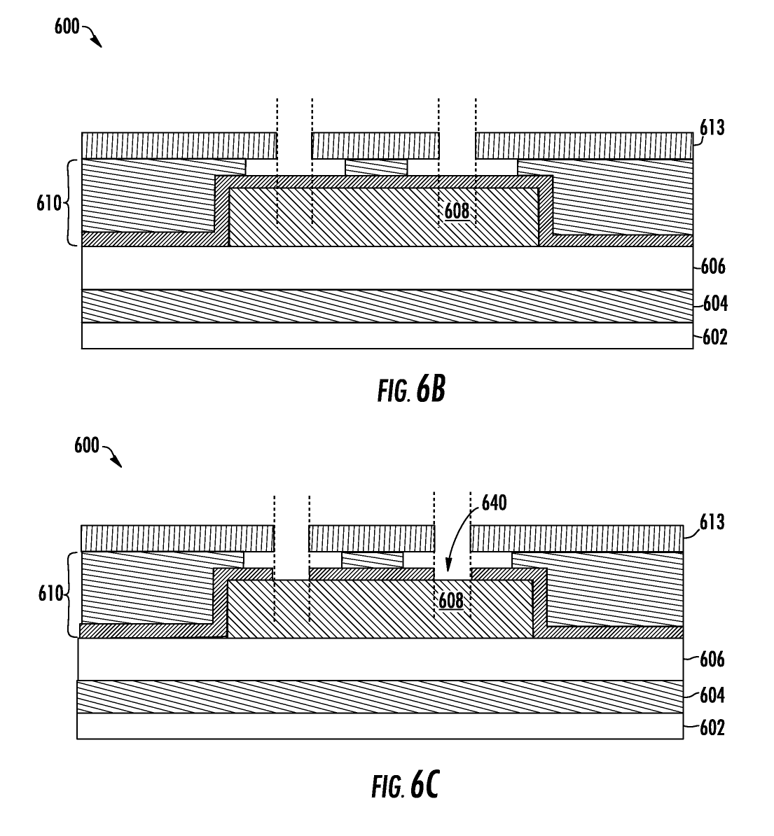

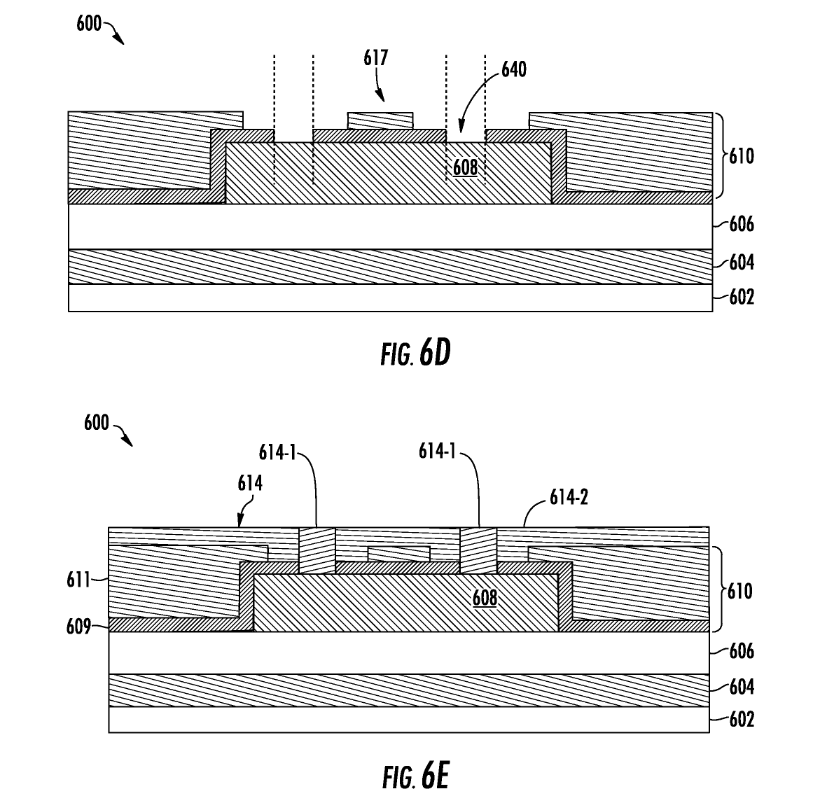

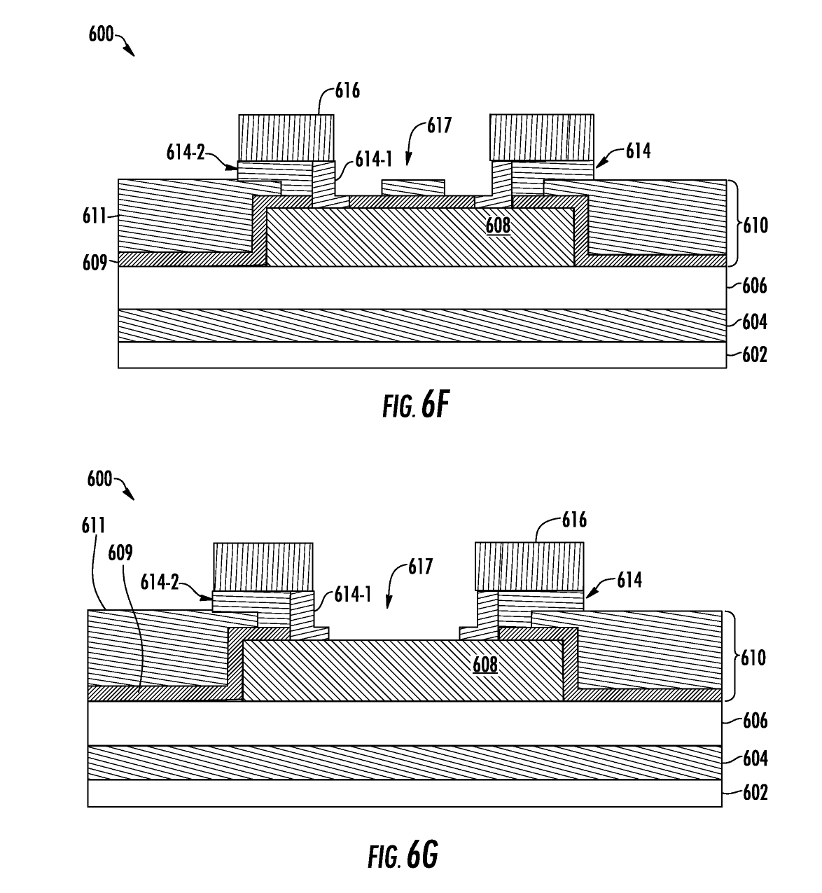

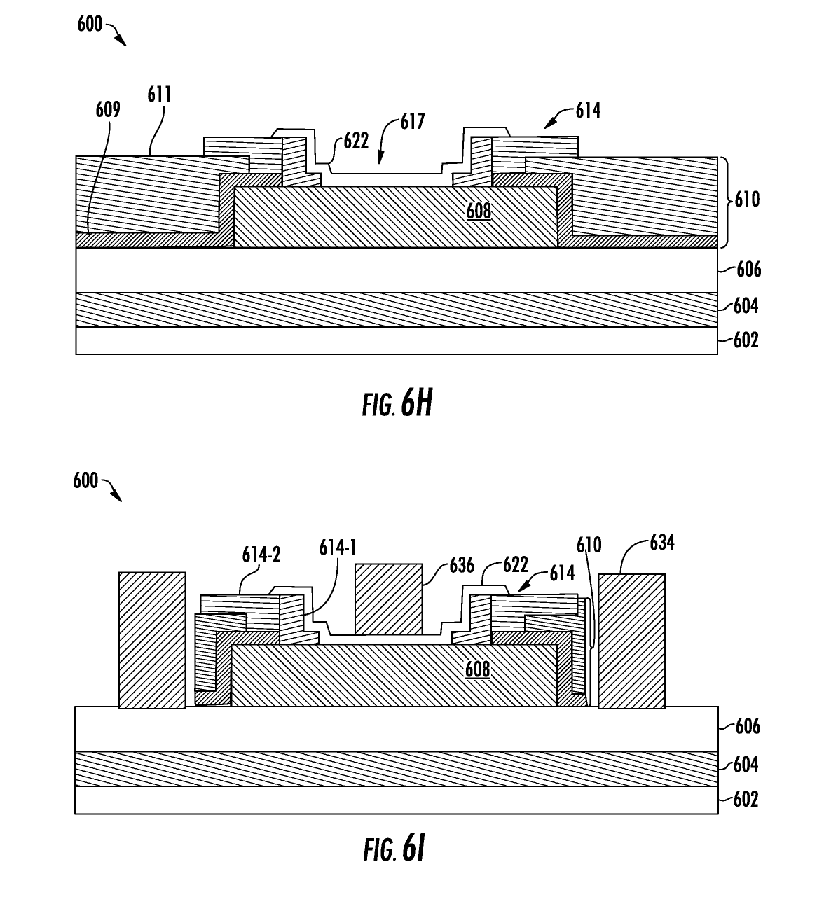

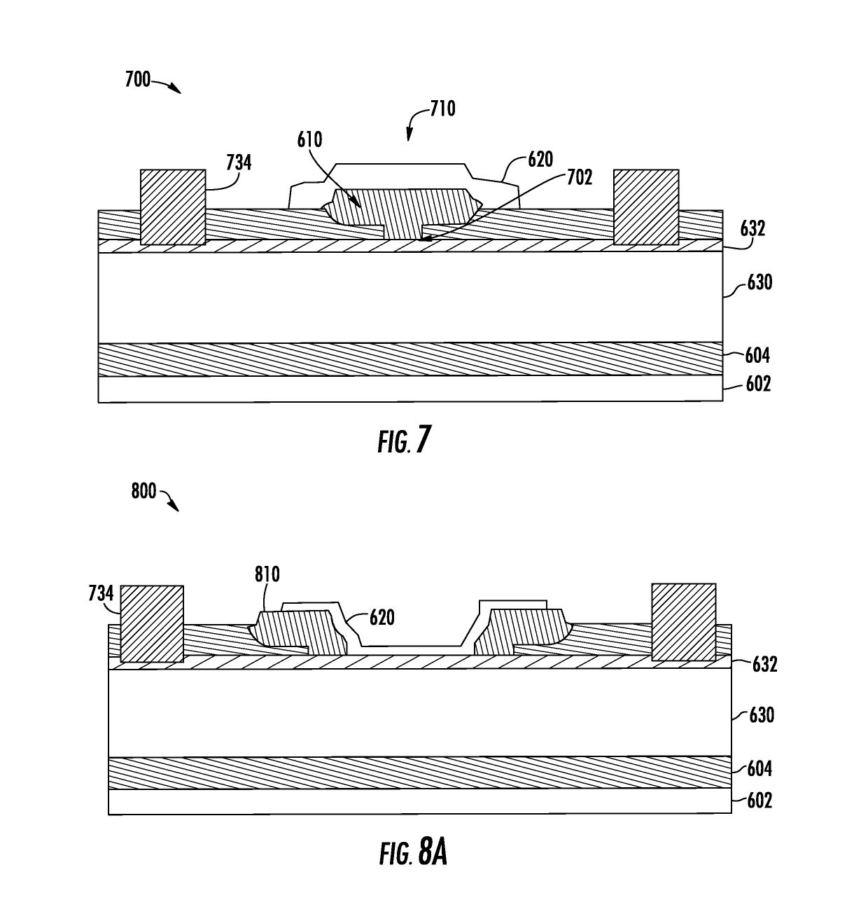

FIGS. 6A through 6I are cross sectional views of one embodiment of a vertical Schottky diode 600 corresponding to stages of one embodiment of a method of fabricating the vertical Schottky diode 600. FIG. 6A illustrates the results of a deposition of a dielectric layer 610 over a GaN N-epi voltage sustaining layer 608 formed over a buried layer 606, a buffer layer 604 and a substrate 602. In the embodiment of FIG. 6A, the dielectric layer 610 comprises a nitride layer 611 formed over an oxide layer 609. In other embodiments, the dielectric layer 610 comprises silicon nitride, AlSiN, oxide, oxynitride, ALN, or combinations thereof. In another embodiment, the stages of fabrication similar to FIGS. 5A and 5B are achieved before the dielectric deposition of FIG. 6A is performed.

In FIG. 6B, a photoresist mask 613 is patterned, a guard ring pattern is exposed, and the dielectric layer 610 is etched isotropically to define the lateral field plate extent. In another embodiment, a mask is added to define the lateral field plate extent. A dry etch of the dielectric layer 610 is performed using the resist mask 613 in FIG. 6C to form guard ring pattern 640. FIG. 6C specifically shows etching the oxide layer 609. FIG. 6D illustrates the vertical Schottky diode 600 after stripping the resist mask 613. A Schottky opening region 617 is formed as a result of the isotropic selective etching performed as shown in FIG. 6D.

FIG. 6E depicts P-GaN (or AlGaN) layer 614 grown using a non-selective “blanket epi” technique or by a SEG-ELO technique which leads to growth of non-mono-crystalline material 614 over the dielectric mask regions (for example, when fast growth rates are used). The P-GaN (or AlGaN) grown over the GaN N-Epi layer 614-1 is mono-crystalline, whereas the P-GaN (or AlGaN) grown over other layers 614-2 has a nano-, micro-, or polycrystalline structure. In one embodiment, any exposed nitride layer 611 is removed selectively when an oxide layer is used for the P-GaN epi growth. Embodiments using nitride or oxynitride instead of oxide where the nitride was exposed during the epi growth are improved because nitride based films act is a more effective nucleation layer (that is, it has higher stability at high temperature) and is more stable during the epi growth, and the presence of oxide can result in some counter doping of the P-type GaN (or AlGaN) if the oxide dissociates during a high temperature Metal-Organic Chemical Vapor Deposition (MOCVD) epitaxial growth epi process (that is, hydrogen dissociates SiO2 into Si and oxygen, and Si is an N-type dopant in GaN or AlGaN).

In FIG. 6F, a Schottky opening mask 616 has been patterned and the exposed GaN or AlGaN etched to expose the dielectric 610. In one embodiment, edges of a Schottky opening region 617 are within the P-GaN or AlGaN guard ring 614, where it is in contact with the voltage sustaining layer 608. FIG. 6G shows the dielectric 610 that remained within the Schottky opening region 617 etched to expose the voltage sustaining layer 608. In FIG. 6H, the resist 616 has been etched and the wafer cleaned. Schottky metal 622 has patterned, which in one embodiment, extends outside the P-guard ring structure 614 to provide additional field plating. FIG. 6I depicts a patterned cathode electrode 634 and anode electrode 636.

One implementation of the embodiment shown in FIG. 6I comprises approximately the following thicknesses: 200 to 2000 μm for the substrate layer 602, 0.1 to 5 μm for the buffer layer 604, 0.1 to 5 μm for the buried layer 606, 0.5 to 9 μm for the voltage sustaining layer 608, 0.01 to 2 μm for the dielectric layer 610, and 500 to 5000 Å for the Schottky metal 622. The thickness of the P-type guard ring 614 is approximately 100 to 10,000 Å and the width may be in within the 0.1 to 2 μm range, depending on the ability to pattern small dimensions. However, this is to be understood as an exemplary non-limiting embodiment, and other embodiments may comprise different dimensions.

FIG. 7 is a cross sectional view of one embodiment of a lateral PN junction 702 diode 700 having a double field plate 710. An anode/ohmic or Schottky metal 620 overlapping a P-AlGaN guard ring 610 forms the double field plate 710. The P-AlGaN (or GaN) guard ring 610 contacts a carrier-doner layer 632 comprising AlGaN formed over GaN layer 630. In one implementation, a P+ GaN or AlGaN layer is grown on the P-AlGaN (or GaN) guard ring 610 to reduce contact resistance. In this lateral PN junction diode 700, current flows from the anode (for example, lateral PN junction 702) to a cathode 734. The breakdown voltage is set by a lateral spacing from the anode edge 702 to a contact edge of cathode 734. In the forward bias condition, current flows through the 2DEG (two dimensional electron gas) formed in the GaN layer 630 (also referred to as a buffer or channel layer) immediately under the AlGaN or InAlN carrier-donor layer 632. In an embodiment implementing AlGaN or GaN, a lateral spacing of 10 μm yields a breakdown voltage between approximately 500 and 1000 V. Other embodiments of lateral diodes implementing a guard ring comprises InAlN over GaN, or another combination of layers to form lateral devices based on 2DEG (2 dimensional electron gas). Different implementations comprise various ring or “race track” style layouts, for example, an anode electrode surrounds a cathode electrode, or vice versa.

Alternative embodiments of a lateral Schottky diode comprise different semiconductor layers. For example, one embodiment of a lateral Schottky diode includes the following layer combination: a substrate, a stress relief layer, a buffer or channel layer (of GaN, for example), a thin binary-barrier layer (comprising, for example, AlN at approximately 5 to 25 Å thick), a carrier-donor layer (comprising, for example, AlGaN with Al making up approximately 25%, or InAlN with In making up approximately 10-25%), and a cap or passivation layer (comprising, for example, GaN at approximately 5 to 30 Å thick, AlN passivation, or SiN passivation). The thin binary-barrier layer improves the carrier density in the 2DEG. The cap or passivation layer can be un-doped for low voltage applications or doped N+ to reduce contact resistance.

FIGS. 8A and 8B are embodiments of a lateral Schottky diode having P-GaN overlap. FIG. 8A depicts a lateral Schottky diode 800 comprising a self-aligned merged guard ring and field plate 810 which forms a ring around a Schottky contact region. The merged guard ring and field plate 810 comprises P-AlGaN or GaN. FIG. 8B describes a lateral Schottky diode 850 having a double field plate. Schottky metal 860 overlaps the field plated guard ring 810 to form the double field plate.

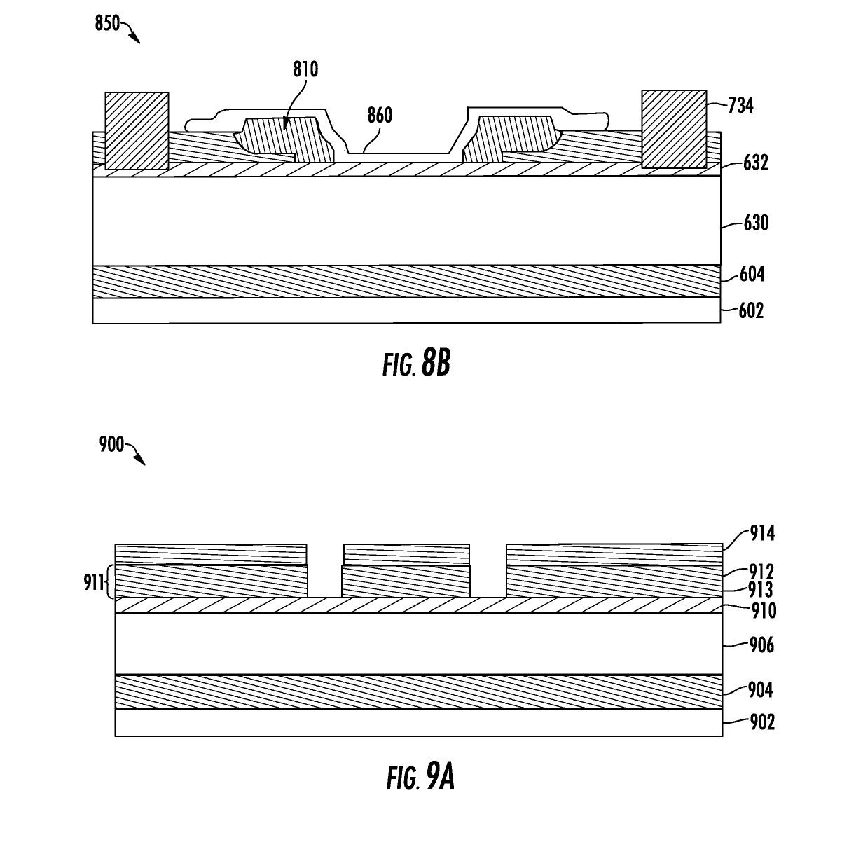

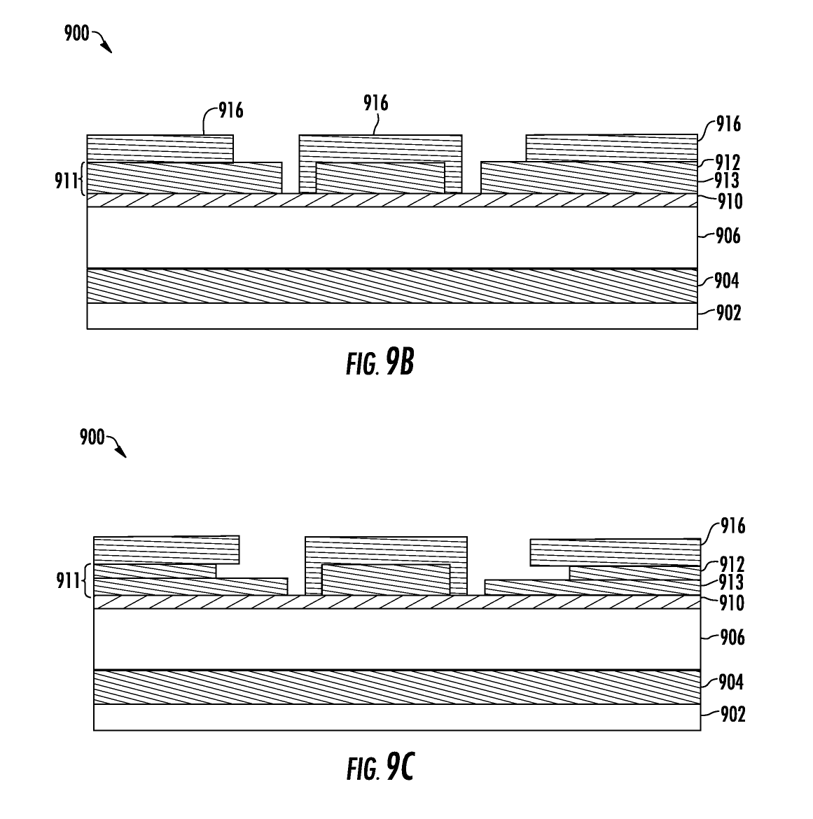

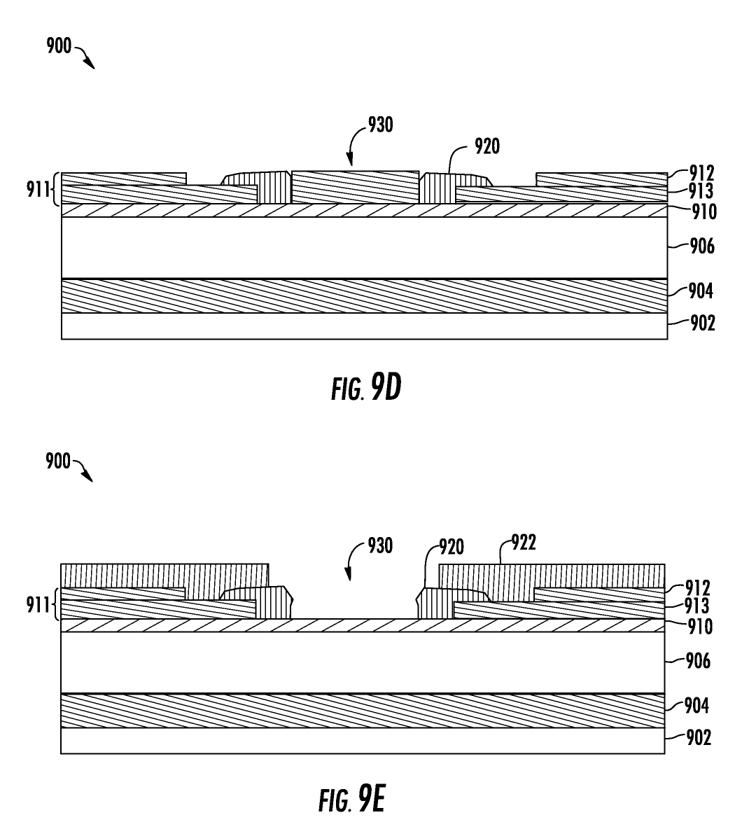

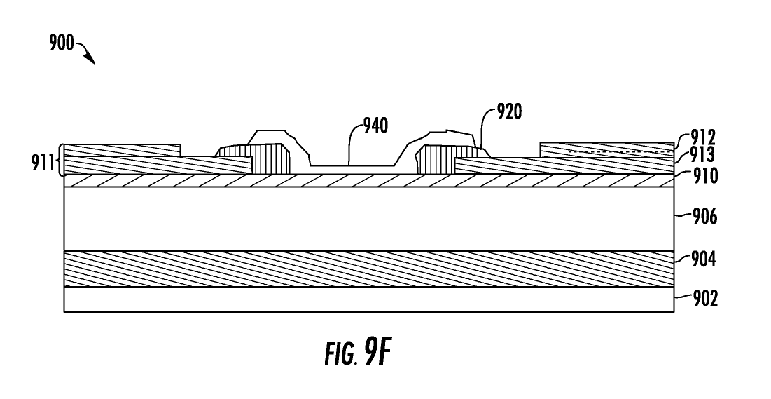

FIGS. 9A through 9F are cross sectional views of one embodiment of a lateral Schottky diode 900 corresponding to stages of one embodiment a method of fabricating the lateral Schottky diode 900. A carrier donor layer 910 is formed over a buffer or channel layer 906, which is formed over a stress relief or buffer layer 904 on a substrate 902. Implementations of the substrate include Si (for example, with <111> orientation), Sapphire (for example, c-plane), Silicon Carbide, SOD, silicon on diamond on silicon, or any other substrate material. A lateral isolation is performed by implantation or mesa etching of the carrier donor layer 910 to eliminate the 2DEG and hence isolate the device area from the surrounding regions. A dielectric 911 is deposited over the carrier donor layer 910. In this embodiment, the carrier donor layer 910 comprises AlGaN with Al in approximately a 10-30% range. In another embodiment, the carrier donor layer 910 comprises InAlN with In in approximately a 5-25% range. In one embodiment, the dielectric 911 is a dielectric stack comprising a top dielectric 912 over a bottom dielectric 913. Some embodiments of the dielectric 911 are composed of nitride, nitride oxide, or oxynitride with oxide underneath and above. A Schottky ring mask 914 is patterned over the dielectric 911, and the dielectric 911 is dry etched to expose the semiconductor layer 910. As known to one of ordinary skill in the art, the epi structure and the purpose of the layers described herein in a lateral Schottky embodiment may be different from that described above with respect to a vertical Schottky embodiment.

In FIG. 9B, a strip resist is performed to remove the Schottky ring mask 914. A second resist 916 is patterned to form a field plate region. FIG. 9C shows the results of an isotropic etch of the top dielectric 912, forming a recess or undercut for the field plate. In FIG. 9D, the second resist 916 is removed. A vertical wall in Schottky contact region 930 is tall enough to constrain growth of a guard ring 920. The guard ring 920 is grown selectively with ELO. In some embodiment, the guard ring 920 comprises P-type GaN, AlGaN, or InAlN. Other embodiments of the guard ring 920 are grown non-selectively. In such an embodiment, an etch is performed to remove any grown GaN or AlGaN from unwanted areas.

In FIG. 9E, a Schottky mask 922 is patterned. The dielectric 911 over the Schottky contact region 930 is etched to expose the Schottky contact region 930. FIG. 9F shows the results of stripping the mask 922 and depositing and patterning Schottky metal 940 over the Schottky contact region 930. In other embodiments, a cathode is patterned, the dielectric further etched, metal interconnects are formed, and the device 900 is passivated.

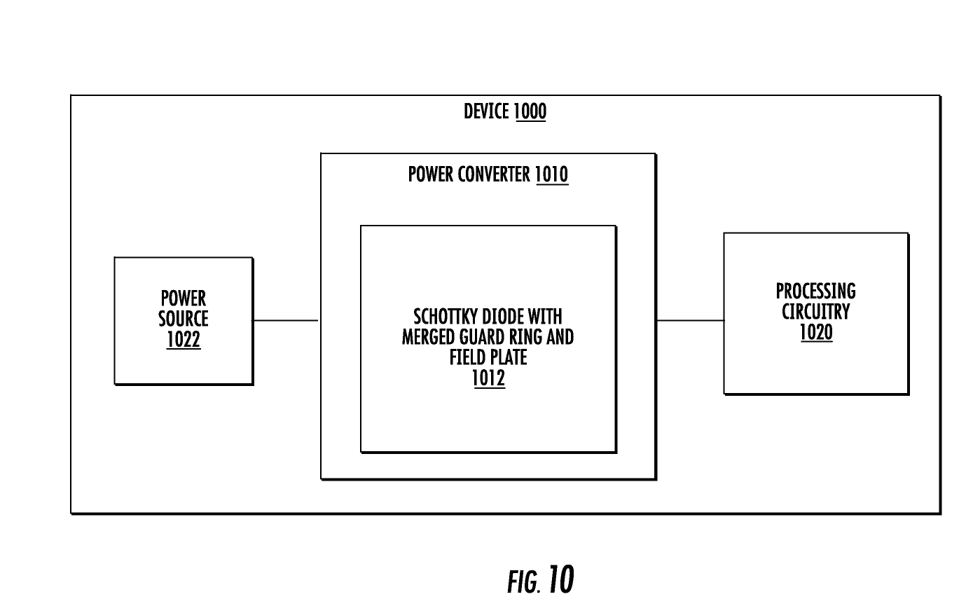

FIG. 10 is a device 1000 comprising at least one Schottky diode with a merged guard ring and field plate 1012. The device 1000 comprises a power converter 1010 coupled to a power source 1022 and processing circuitry 1020. The power converter 1010 incorporates the at least one Schottky diode with a merged guard ring and field plate 1012. In one embodiment, the device 1000 comprises a Schottky diode having a merged guard ring and double field plate. In another embodiment, the power source 1022 is external to the device 1000. The device 1000 is any electronic device, such as a cell phone, computer, navigation device, microprocessor, a high frequency device, etc. In one embodiment, the power converter 1010 is a high-current and high-voltage power converter. Embodiments of the field plated diodes described herein can be implemented in other power devices, high-power density and high-efficiency DC power converters, and high voltage AC/DC power converters, or any other application where a Schottky diode or lateral P-N junction diode is used.

Some embodiments described herein provide Schottky diodes with reduced leakage. Some embodiments of methods of fabrication provide fewer steps of forming the Schottky diode, reducing the cost of fabrication. In one embodiment, a single step forms both a P-N guard ring and a field plate. Growing a p-guard ring results in less damage and leakage than implantation and is a lower temperature process. One embodiment described herein comprises a diode having a breakdown voltage enhancing structure consisting of a merged guard ring and field plate structure which are of an opposite conductivity type as the cathode doping. The guard ring is in contact with a cathode region adjacent to Schottky contact opening. The guard ring and the field plate are made of the same material and the field plate is in electrical contact with guard ring and overlaps dielectrics which surround the Schottky contact opening.

In the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

A number of embodiments of the invention defined by the following claims have been described. Nevertheless, it will be understood that various modifications to the described embodiments may be made without departing from the spirit and scope of the claimed invention. Features and aspects of particular embodiments described herein can be combined with or replace features and aspects of other embodiments. Accordingly, other embodiments are within the scope of the following claims.

What is claimed is:

1. A Schottky diode, comprising:
a merged guard ring and field plate defining a Schottky contact region; and
a Schottky metal formed at least partially over the Schottky contact region and at least partially over the merged guard ring and field plate.

2. The Schottky diode of claim 1, further comprising:
a voltage sustaining layer, wherein at least a portion of the merged guard ring and field plate contacts the voltage sustaining layer;
wherein a Schottky contact is formed between the Schottky metal and the voltage sustaining layer.

3. The Schottky diode of claim 2, wherein the voltage sustaining layer comprises one of gallium nitride (GaN), aluminum gallium nitride (AlGaN), silicon (Si), germanium (Ge), silicon germanium (SiGe), indium gallium nitride (InGaN), indium phosphide (InP), indium aluminum nitride (InAlN), or gallium arsenide (GaAs).

4. The Schottky diode of claim 2, wherein the merged guard ring and field plate is a p-type material and forms a P-N junction with the voltage sustaining layer.

5. The Schottky diode of claim 1, further comprising:
a carrier-donor layer, wherein the merged guard ring and field plate is formed at least partially over the carrier-donor layer.

6. The Schottky diode of claim 5, wherein:
the merged guard ring and field plate comprises gallium nitride (GaN); and
the carrier-donor layer comprises one of aluminum gallium nitride (AlGaN) or indium aluminum nitride (InAlN) and forms a two dimensional electron gas (2DEG) below the merged guard ring and field plate.

7. The Schottky diode of claim 5, further comprising:
a substrate;
a stress relief layer formed over the substrate;
a channel layer comprising GaN;
a binary-barrier layer formed over the channel layer; and
a passivation layer formed over the carrier-donor layer.

8. The Schottky diode of claim 1, wherein the merged guard ring and field plate comprises one of gallium nitride (GaN), positively doped aluminum gallium nitride (P-AlGaN), or positively doped indium aluminum nitride (P-InAlN).

9. The Schottky diode of claim 1, wherein the Schottky metal is formed over the entire merged guard ring and field plate.

10. The Schottky diode of claim 1, further comprising:
a cathode formed over a buried region; and
a buffer layer formed over a substrate, wherein the buried region is formed over the buffer region;
wherein the cathode is of a first conductivity type; and
wherein the merged guard ring and field plate is of a second conductivity type opposite the first conductivity type.

11. The Schottky diode of claim 1, wherein an upper portion of the merged guard ring and field plate is doped to a higher concentration that a lower portion of the merged guard ring and field plate.

12. A Schottky diode, comprising:
a substrate, wherein a voltage sustaining layer is located over the substrate;
a merged guard ring and field plate in contact with at least part of the voltage sustaining layer;
a Schottky metal formed over the voltage sustaining layer in a region defined by the merged guard ring and field plate and extending at least partially over the merged guard ring and field plate.

13. The Schottky diode of claim 12, wherein the merged guard ring and field plate extends at least partially over a dielectric layer.

14. The Schottky diode of claim 12, wherein the Schottky metal is formed over the entire merged guard ring and field plate.

15. The Schottky diode of claim 12, wherein the merged guard ring and field plate comprises a first portion of a first crystalline type and a second portion of a second crystalline type.

16. The Schottky diode of claim 15, wherein the first portion contacts the voltage sustaining layer and the second portion is formed over the dielectric layer.

17. The Schottky diode of claim 15, wherein the first crystalline type is of a higher quality than the second crystalline type.

18. The Schottky diode of claim 15, wherein:
the first crystalline type is mono-crystalline; and
the second crystalline type is one of amorphous, nano-crystalline, micro-crystalline, or poly-crystalline.

19. The Schottky diode of claim 12, further comprising:
a cathode formed over a buried region; and
a buffer layer formed over the substrate.

20. The Schottky diode of claim 19, wherein:
the cathode is of a first conductivity type; and
the merged guard ring and field plate is of a second conductivity type opposite the first conductivity type.

21. The Schottky diode of claim 12, wherein the dielectric layer comprises one or more layers comprising an oxide layer, a nitride layer, an oxynitride layer.

22. The Schottky diode of claim 12, wherein the dielectric layer is stepped.

23. The Schottky diode of claim 12, wherein:
the voltage sustaining layer comprises one of gallium nitride (GaN), aluminum gallium nitride (AlGaN), silicon (Si), germanium (Ge), silicon germanium (SiGe), indium gallium nitride (InGaN), indium aluminum nitride (InAlN), indium phosphide (InP), or gallium arsenide (GaAs); and
the merged guard ring and field plate comprises one of positively doped gallium nitride (P-GaN) or positively doped InAlN;
the substrate comprises one of Si, sapphire, silicon on diamond, silicon carbide, GaN, or InP; and
the Schottky metal comprises one of nickel, titanium, cobalt, aluminum, platinum, or tantalum, or combinations thereof.

24. The Schottky diode of claim 12, wherein the merged guard ring and field plate is self-aligned.

25. The Schottky diode of claim 12, wherein an upper portion of the merged guard ring and field plate is doped at a higher concentration than the rest of the merged guard ring and field plate.

26. A method of forming a diode, comprising:
forming a guard ring along an edge of a Schottky contact region, wherein the guard ring is partially coplanar with and partially extending above the Schottky contact region; and
depositing a Schottky metal over at least part of the Schottky contact region and at least part of the guard ring.

27. The method of claim 26, further comprising:
forming a dielectric layer;
patterning a first resist over at least the dielectric layer to form a guard ring pattern;
etching the dielectric layer to form a guard ring region, wherein the guard ring region contacts the edge of the Schottky contact region;
stripping the first resist;
patterning a second resist over at least part of the guard ring to form a Schottky opening;
etching the exposed guard ring not covered by the second resist and a portion of the dielectric layer within the Schottky opening; and
stripping the second resist.

28. The method of claim 27, further comprising isotropically etching the dielectric layer to define a lateral extent of a field plate.

29. The method of claim 27, wherein etching a portion of the dielectric layer further comprises performing a dry etch to remove the portion of the dielectric layer.

30. The method of claim 26, further comprising:
forming a voltage sustaining layer, wherein the guard ring is partially formed on the voltage sustaining layer.

31. The method of claim 30, further comprising:
etching a portion of the voltage sustaining layer to expose the cathode layer; and
depositing the dielectric layer over exposed cathode layer.

32. The method of claim 30, wherein forming a dielectric layer further comprises:
depositing a first oxide or oxynitride layer over the voltage sustaining layer;
depositing a nitride layer over the first oxide or oxynitride layer; and
depositing a second oxide or oxynitride layer over the nitride layer.

33. The method of claim 30, further comprising:
forming a cathode electrode over a buried layer;
passivating the diode; and
patterning an interconnect metal, wherein the interconnect metal extends over a field plate to provide double field plating.

34. The method of claim 26, wherein forming a guard ring comprises growing the guard ring in the guard ring region using a selective epitaxial growth (SEG) technique.

35. The method of claim 26, wherein forming a guard ring comprises growing the guard ring in the guard ring region using an epitaxial lateral overgrowth (ELO) technique.

36. The method of claim 26, further comprising:
forming a carrier-donor layer, wherein the guard ring is partially formed on the carrier-donor layer.

37. The method of claim 26, wherein forming a guard ring further comprises selectively growing the guard ring to form a self-aligned merged guard ring and field plate.

38. The method of claim 37, wherein the guard ring comprises a first crystalline structure and the field plate comprises a second crystalline structure.

39. The method of claim 26, wherein depositing a Schottky metal comprises depositing the Schottky metal over the entire guard ring.

40. The method of claim 26, wherein:
the guard ring is grown at least partially over a dielectric; and
the Schottky metal is formed over the portion of the guard ring not over the dielectric, and wherein the Schottky metal is not formed over the dielectric.

41. The method of claim 26, further comprising:
forming a dielectric layer over a buffer layer and a voltage sustaining layer, wherein the dielectric layer comprises a nitride layer formed over an oxide layer;
patterning a first resist over at least the dielectric layer to form a guard ring pattern;
laterally etching the nitride layer to form a guard ring region and a lateral extent of a field plate, wherein the guard ring region contacts the edge of the Schottky contact region;
etching the oxide layer exposed by the first resist;
stripping the first resist;
wherein forming a guard ring comprises growing one of positively doped gallium nitride (P-GaN), positively doped aluminum gallium nitride (P-AlGaN), positively doped indium gallium nitride (P-InGaN), or positively doped indium aluminum nitride (P-InAlN) after the first resist is stripped, wherein a portion of the guard ring grown directly over the voltage sustaining layer has a first crystalline structure and at least part of the guard ring grown elsewhere has a second crystalline structure;
patterning a second resist;
etching at least portion of the guard ring exposed by the second resist; and
stripping the second resist.

42. The method of claim 41, wherein forming a guard ring further comprises growing the guard ring using one of a non-selective blanket epi technique, a selective epitaxial growth (SEG) technique, or an epitaxial lateral overgrowth (ELO) technique.

43. The method of claim 26, further comprising:
forming a voltage sustaining layer over a buried layer;
performing a lateral isolation by etching a portion of the voltage sustaining layer;
depositing a dielectric layer over the voltage sustaining layer;
patterning a ring mask over the dielectric layer;
etching the dielectric layer exposed by the ring mask to expose the voltage sustaining layer;
stripping the ring mask;
patterning a first resist to define a field plate region;
performing an isotropic etch of at least part of the dielectric layer;
stripping the first resist;
selectively growing the guard ring using an epitaxial lateral overgrowth (ELO) technique;
patterning a second resist to define a junction region;
etching surfaces exposes by the second resist; and
stripping the second resist.

44. A diode, comprising:
a cathode having a first conductivity type;
a Schottky contact opening within a dielectric region; and
a breakdown voltage enhancing structure adjacent to the Schottky contact opening having a second conductivity type opposite to the first conductivity type comprising a merged guard ring and a field plate;
wherein the guard ring and the field plate comprise a first material;
wherein the guard ring contacts the cathode; and
wherein the field plate is in electrical contact with the guard ring and overlaps the dielectric region.

45. The diode of claim 44, further comprising an anode metal formed over the Schottky contact opening and at least a portion of the merged guard ring and field plate.

46. The diode of claim 44, wherein the anode metal is formed over the entire merged guard ring and field plate and provides double field plating.

47. A diode, comprising:
a cathode having a first conductivity type;
a contact opening within a dielectric region; and
a breakdown voltage enhancing structure within the contact opening having a second conductivity type opposite to the first conductivity type comprising a merged guard ring and a field plate;
wherein the merged guard ring and the field plate comprise a first material;
wherein the guard ring is in electrical contact with a voltage sustaining layer; and
wherein the field plate is in electrical contact with the guard ring and overlaps the dielectric region.

48. The diode of claim 47, wherein the contact between the guard ring and the voltage sustaining layer forms a P-N junction.

49. An electronic device, comprising:
a power converter including at least one diode, wherein the diode comprises:
a substrate, wherein a breakdown voltage enhancing structure is located over the substrate;
a merged guard ring and field plate formed along an edge of a Schottky contact region;
a metal formed over the breakdown voltage enhancing structure in a region defined by the merged guard ring and field plate and extending at least partially over the merged guard ring and field plate; and
processing circuitry coupled to the power converter.

50. The device of claim 49, wherein the at least one diode is one of a vertical Schottky diode, a lateral Schottky diode, or a P-N junction diode.

51. The device of claim 49, wherein the merged guard ring and field plate extends at least partially over a dielectric layer.

52. The device of claim 49, wherein the metal is formed over the entire merged guard ring and field plate.
